(19) United States
(12) Patent Application Publication
(10) Pub. No.: US 2020/0184121 A1
(43) Pub. Date: Jun. 11, 2020

(54) SYSTEMS AND METHODS FOR INCREASING READABILITY OF PRODUCT AND MANUFACTURING INFORMATION (PMI)

(71) Applicant: General Electric Company, Schenectady, NY (US)

(72) Inventor: Dawid Tadeusz MACHALICA, Warszawa (PL)

(21) Appl. No.: 16/704,438

(22) Filed: Dec. 5, 2019

(30) Foreign Application Priority Data
Dec. 10, 2018 (PL) P.428097

(51) Int. Cl. G06F 30/12; G06N 20/00

(52) U.S. Cl. CPC G06F 30/12; G06F 30/17; G06N 20/00

(57) ABSTRACT

The present application is directed to techniques for improving the readability of product and manufacturing information (PMI) associated with models, such as computer-aided design models. In one embodiment, a system includes a processor for implementing a computer-aided technology (CAx) system. The CAx system includes a graphical-user-interface (GUI) configured to present a first view of a computer-aided design (CAD) model that includes at least one part. Additionally, the system includes memory storing instructions configured to cause the processor to generate a product and manufacturing information (PMI) associated with the CAD model, present the CAD model with the PMI via the GUI, and determine a PMI readability metric.

### CROSS-REFERENCE TO RELATED APPLICATIONS

This specification is based upon and claims the benefit of priority from Polish patent application number PL P.428097 filed on Dec. 10, 2018, the entire contents of which are incorporated herein by reference.

### BACKGROUND

The subject matter disclosed herein relates to systems and methods for increasing readability of product and manufacturing information (PMI) associated with a model, such as models for industrial machine parts.

Industrial machines and machine parts may be developed for a particular purpose, such as a compressor blade developed to compress air. The machine or part may contain many features shared with many portions of the part. Furthermore, these machine parts may include complex designs with many complex features. These features are typically individually managed in a computer-aided design (CAD) system, despite their relationship with other components. As such, 3-dimensional (3D) models and/or 2-dimensional (2D) models may be generated to facilitate the manufacturing of the machines and/or the parts. Generally, the features associated with the part may include an attribute of the feature displayed as product and manufacturing information (e.g., a PMI object), and displaying the PMI object may require a user to manually identify the features associated with the PMI object.

The PMI object may include text (e.g., indicative of PMI or characteristics of a feature) displayed on the model of the part, annotations, callouts, dimensions, notes, and so forth displayed on the drawing and/or model to provide PMI information. In some embodiments, PMI objects may include a visual indication providing PMI information associated with a specific feature designated with the PMI object. Drawings and/or the models of the parts or assemblies may contain PMI objects used to describe a feature of the part. For example, a model may include a first PMI object indicating a first type of PMI information, such as a length of the part; a second PMI object indicating a second type of PMI information, such as a length of an indentation of the part; a third PMI object indicating a third set of PMI information, such as dimensions and tolerances of a beveled edge of the part; and the like. It may be beneficial to improve the presentation of PMI objects.

### BRIEF DESCRIPTION

Certain embodiments commensurate in scope with the originally claimed subject matter are summarized below. These embodiments are not intended to limit the scope of the claimed subject matter, but rather these embodiments are intended only to provide a brief summary of possible forms of the claimed subject matter. Indeed, the claimed subject matter may encompass a variety of forms that may be similar to or different from the embodiments set forth below.

In a first embodiment, a system includes a processor for implementing a computer-aided technology (CAx) system. The CAx system includes a graphical-user-interface (GUI) configured to present a first view of a computer-aided design (CAD) model that includes at least one part. Additionally, the system includes memory storing instructions configured to cause the processor to generate a product and manufacturing information (PMI) associated with the CAD model, present the CAD model with the PMI via the GUI, and determine a PMI readability metric.

In a second embodiment, a computer-implemented method includes presenting a first computer-aided design (CAD) model that includes at least one part in a graphical-user-interface (GUI). The computer-implemented method also includes generating a product and manufacturing information (PMI) associated with the CAD model, presenting, via the GUI, the CAD model with the PMI, determining a PMI readability metric, comparing the PMI readability metric to a threshold, and altering the presentation of the model and the PMI when the PMI readability is less than the threshold.

In a third embodiment, a tangible, non-transitory, computer-readable medium, includes computer-readable instructions that, when executed by one or more processors of a computer, cause the one or more processors to present a first view of a computer-aided design (CAD) model that includes at least one part. The instructions are also configured to cause the one or more processors to generate a product and manufacturing information (PMI) associated with the CAD model, display a first view of the CAD model with the PMI, determine a PMI readability metric of the first view, compare the PMI readability metric to a threshold, and present a second view of CAD model and the PMI when the PMI readability metric is less than the threshold.

### BRIEF DESCRIPTION OF THE DRAWINGS

These and other features, aspects, and advantages of the present claimed subject matter will become better understood when the following detailed description is read with reference to the accompanying drawings in which like characters represent like parts throughout the drawings, wherein:

FIG. 1 is a block diagram of an embodiment of a computer-aided technology (CAx) system, in accordance with an aspect of the present disclosure;

FIG. 2 is a block diagram of a certain components of the CAx system of FIG. 1, in accordance with an aspect of the present disclosure;

FIG. 3 is block diagram of an industrial system that may be conceived, designed, engineered, manufactured, and/or service and tracked by the CAx system of FIG. 1, in accordance with an aspect of the present disclosure;

FIG. 4 illustrates a CAD model with attached PMI objects, in accordance with an aspect of the present disclosure;

FIG. 5 illustrates a more readable view of the CAD model of FIG. 4, in accordance with an aspect of the present disclosure; and

FIG. 6 is a flowchart of a process for increasing readability of PMI associated with a model, in accordance with an aspect of the present disclosure;

### DETAILED DESCRIPTION

One or more specific embodiments of the present disclosure will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present claimed subject matter, the articles “a,” “an,” “the,” and “said” are intended to mean that there are one or more of the elements. The terms “comprising,” “including,” and “having” are intended to be inclusive and mean that there may be additional elements other than the listed elements.

Designing a machine or part may include certain systems and methods described in more detail below that produce a model of the part. For example, the model of the part may be created as a model-based definition included in a 2-dimensional (2D) or a 3-dimensional (3D) computer-aided design (CAD) model. The techniques described herein may include the CAD model containing all part dimensional and tolerance information.

After creating the 3D CAD part, hereinafter referred to as the “part,” a drawing and/or model-based definition (e.g., a model with PMI) of the part may be generated by a computer-aided technologies (e.g., CAx) system, whereby the drawing and/or model-based definition may be used to manufacture the part according to the PMI objects (e.g., annotations, callouts, notes, text, etc.) displayed on the drawing and/or model. “Model,” used hereinafter, may be used to describe a 2D model, a 3D model, or any other view of a part that may be displayed on a screen, the window of a CAD system, or a sheet of paper as a drawing. As such, drawings and/or the models may contain PMI objects used to describe a feature of the part. For example, there may be an PMI object indicating that an edge has a certain bevel, a certain tolerance, finish, and the like. Likewise, three similar through-holes on a front face of a part, that the part has certain faces, certain edges, certain curves, and so on.

Generally, a designer (e.g., person developing the part and its features) may manually identify certain information (e.g., Product and Manufacturing Information (PMI)) for parts in the first model. The details may be used to aid in the manufacturing of the part. For example, each hole may have a PMI information indicating the dimensions of the hole, tolerances for various objects (e.g., faces, edges, holes, etc.), orientation, location, run-out, and so on. In some embodiments, the PMI may adhere to standards such as ASME Y14.41-2003 Digital Product Data Definition Practices and ISO 1101:2004 Geometrical Product Specifications (GPS)—Geometrical tolerancing. However, in some cases, the model and/or PMI may be oriented in a manner that makes it difficult to read the PMI associated with the model. For example, the PMI may be oriented in a plane that runs generally parallel to viewpoint of person viewing the model. To increase the visibility of PMI that are presented with models (e.g., CAD models), the CAx system may determine whether PMI is readable and adjust the model and/or PMI to become readable when the CAx system determines that the PMI is not readable. Accordingly, models with readable PMI may be generated and presented to users.

In some cases, model-based definitions, which may include models (e.g., models of a parts or assemblies) with PMI, may be manually altered by an engineer. For example, an engineer may alter a view or orientation associated with the model and/or the PMI. To increase efficiency and/or prevent the inaccuracies that may otherwise result from having an engineer manually orient PMI objects and/or parts included in models, present embodiments include systems and methods for automatically reorienting and/or repositioning PMI objects and/or parts of models without dependency on human subjectivity. In this manner, present embodiments help transform a traditionally subjective process of deciding views or orientations for model-based designs, traditionally performed by humans, into a mathematically automated process that is executable via a process-based device.

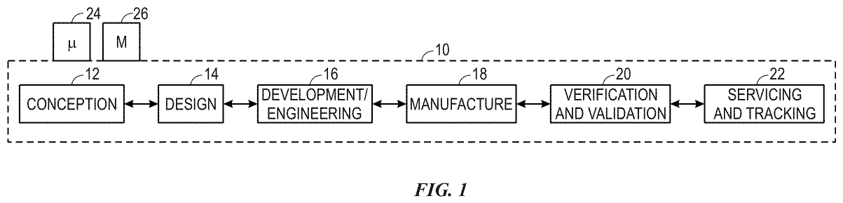

With the foregoing in mind, it may be useful to describe a computer-aided technologies (CAx) system that may incorporate the techniques described herein, for example to improve the generation of PMI objects on model-based definitions. Accordingly, FIG. 1 illustrates an embodiment of a CAx system 10 suitable for providing for a variety of processes, including PLM processes 12, 14, 16, 18, 20, 22. In the depicted embodiment, the CAx system 10 may include support for execution of conception processes 12. For example, the conception processes 12 may produce a set of specifications such as requirements specifications documenting a set of requirements to be satisfied by a design, a part, a product, or a combination thereof. The conception processes 12 may also produce a concept or prototype for the part or product (e.g., machine). A series of design processes 14 may then use the specifications and/or prototype to produce, for example, one or more 3D design models of the part or product. The 3D design models may include solid/surface modeling, parametric models, wireframe models, vector models, non-uniform rational basis spline (NURBS) models, geometric models, 2D manufacturing part and assembly drawings, and the like.

Design models may then be further refined and added to via the execution of development/engineering processes 16. The development/engineering processes may, for example, create and apply models such as thermodynamic models, low cycle fatigue (LCF) life prediction models, multibody dynamics (MBD) and kinematics models, computational fluid dynamics (CFD) models, finite element analysis (FEA) models, and/or 3-dimension to 2-dimension FEA mapping models that may be used to predict the behavior of the part or product during its operation. For example, turbine blades may be modeled to predict fluid flows, pressures, clearances, and the like, during operations of a gas turbine engine. The development/engineering processes 16 may additionally result in tolerances, materials specifications (e.g., material type, material hardness), clearance specifications, and the like.

The CAx system 10 may additionally provide for manufacturing processes 18 that may include manufacturing automation support. For example, additive manufacturing models may be derived, such as 3D printing models for material jetting, binder jetting, vat photopolymerization, powder bed fusion, sheet lamination, directed energy deposition, material extrusion, and the like, to create the part or product. Other manufacturing models may be derived, such as computer numeric control (CNC) models with G-code to machine or otherwise remove material to produce the part or product (e.g., via milling, lathing, plasma cutting, wire cutting, and so on). Bill of materials (BOM) creation, requisition orders, purchasing orders, and the like, may also be provided as part of the manufacture processes 18 (or other PLM processes).

The CAx system 10 may additionally provide for verification and/or validation processes 20 that may include automated inspection of the part or product as well as automated comparison of specifications, requirements, and the like. In one example, a coordinate-measuring machine (CMM) process may be used to automate inspection of the part or product. After the part is inspected, results from the CMM process may be automatically generated via an electronic Characteristic Accountability & Verification (eCAV) system.

A servicing and tracking set of processes 22 may also be provided via the CAx system 10. The servicing and tracking processes 22 may log maintenance activities for the part, part replacements, part life (e.g., in fired hours), and so on. As illustrated, the CAx system 10 may include feedback between the processes 12, 14, 16, 18, 20, 22. For example, data from services and tracking processes 22, for example, may be used to redesign the part or product via the design processes 14. Indeed, data from any one of the processes 12, 14, 16, 18, 20, 22 may be used by any other of the processes 12, 14, 16, 18, 20, 22 to improve the part or product or to create a new part or a new product. In this manner, the CAx system 10 may incorporate data from downstream processes and use the data to improve the part or to create a new part.

The CAx system 10 may additionally include one or more processors 24 and a memory system 26 that may execute software programs to perform the disclosed techniques. Moreover, the processors 24 may include multiple microprocessors, one or more “general-purpose” microprocessors, one or more special-purpose microprocessors, and/or one or more application specific integrated circuits (ASICS), or some combination thereof. For example, the processors 24 may include one or more reduced instruction set (RISC) processors. The memory system 26 may store information such as control software, look up tables, configuration data, etc. The memory system 26 may include a tangible, non-transitory, machine-readable medium, such as a volatile memory (e.g., a random access memory (RAM)) and/or a nonvolatile memory (e.g., a read-only memory (ROM), flash memory, a hard drive, or any other suitable optical, magnetic, or solid-state storage medium, or a combination thereof).

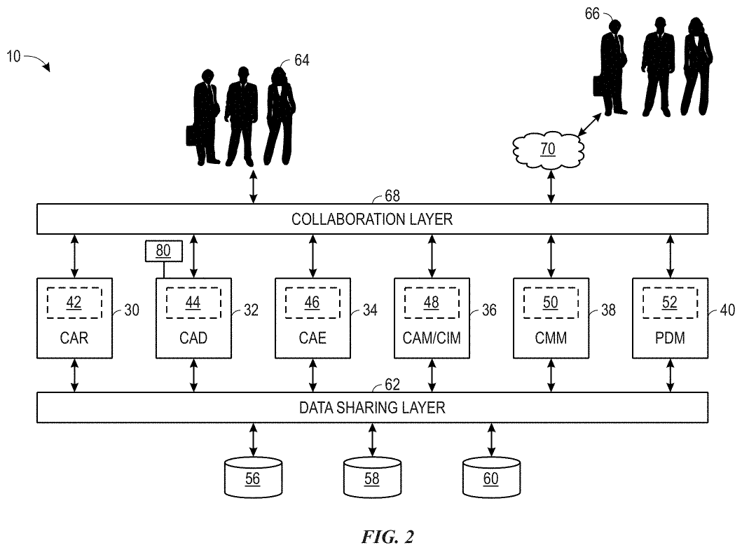

The memory system 26 may store a variety of information, which may be suitable for various purposes. For example, the memory system 26 may store machine-readable and/or processor-executable instructions (e.g., firmware or software) for the processors' 24 execution. In one embodiment, the executable instructions include instructions for a number of CAx based systems, for example software systems, as shown in the embodiment of FIG. 2. More specifically, the CAx system 10 embodiment illustrates a computer-aided requirements capture (CAR) system 30, a computer-aided design (CAD) system 32, a computer-aided engineering (CAE) system 34, computer-aided manufacturing/computer-integrated manufacturing (CAM/CIM) system 36, a coordinate-measuring machine (CMM) system 38, and a product data management (PDM) system 40. Each of the systems 30, 32, 34, 36, 38 and 40 may be extensible and/or customizable, accordingly, each system 30 may include an extensibility and customization system 42, 44, 46, 48, 50, and 52, respectively. Additionally, each of the systems 30, 32, 34, 36, 38 and 40 may be stored in a memory system, such as memory system 26, and may be executable via a processor, such as via processors 24.

In the depicted embodiment, the CAR system 30 may provide for entry of requirements and/or specifications, such as dimensions for the part or product, operational conditions that the part or product is expected to encounter (e.g., temperatures, pressures), certifications to be adhered to, quality control requirements, performance requirements, and so on. The CAD system 32 may provide for a graphical user interface (GUI) suitable to create and manipulate graphical representations of 2D and/or 3D models as described above with respect to the design processes 14. For example, the 3D models may include solid/surface modeling, parametric models, wireframe models, vector models, non-uniform rational basis spline (NURBS) models, geometric models, and the like. The CAD system 32 may provide for the creation and update of the 2D and/or 3D models and related information (e.g., views, drawings, annotations, notes, PMI object, etc.). Indeed, the CAD system 32 may combine a graphical representation of the part or product with other, related information. Further, the CAD system 32 may create the PMI information and objects displayed on various drawings or model-based definitions displaying multiple views and/or orientations of the same part. As discussed below in detail, the CAD system 32 may also determine whether PMI information is readable and alter the appearance of models and/or PMI objects to increase the readability of the PMI objects.

The CAE system 34 may enable creation of various engineering models, such as the models described above with respect to the development/engineering processes 16. For example, the CAE system 34 may apply engineering principles to create models such as thermodynamic models, low cycle fatigue (LCF) life prediction models, multibody dynamics (MBD) and kinematics models, computational fluid dynamics (CFD) models, finite element analysis (FEA) models, and/or 3-dimension to 2-dimension FEA mapping models. The CAE system 34 may then apply the aforementioned models to analyze certain part or product properties (e.g., physical properties, thermodynamic properties, fluid flow properties, and so on), for example, to better match the requirements and specifications for the part or product.

The CAM/CIM system 36 may provide for certain automation and manufacturing efficiencies, for example, by deriving certain programs or code (e.g., G-code) and then executing the programs or code to manufacture the part or product. The CAM/CIM system 36 may support certain automated manufacturing techniques, such as additive (or subtractive) manufacturing techniques, including material jetting, binder jetting, vat photopolymerization, powder bed fusion, sheet lamination, directed energy deposition, material extrusion, milling, lathing, plasma cutting, wire cutting, or a combination thereof. The CMM system 38 may include machinery to automate inspections. For example, probe-based, camera-based, and/or sensor-based machinery may automatically inspect the part or product to ensure compliance with certain geometries, tolerances, shapes, and so on.

The PDM system 40 may be responsible for the management and publication of data from the systems 30, 32, 34, 36, and/or 38. For example, the systems 30, 32, 34, 36, and/or 38 may communicate with data repositories 56, 58, 60 via a data sharing layer 62. The PDM system 40 may then manage collaboration between the systems 30, 32, 34, 36, and/or 38 by providing for data translation services, versioning support, archive management, notices of updates, and so on. The PDM system 40 may additionally provide for business support such as interfacing with supplier/vendor systems and/or logistics systems for purchasing, invoicing, order tracking, and so on. The PDM system 40 may also interface with service/logging systems (e.g., service center data management systems) to aid in tracking the maintenance and life cycle of the part or product as it undergoes operations. Teams 64, 66 may collaborate with team members via a collaboration layer 68. The collaboration layer may include web interfaces, messaging systems, file drop/pickup systems, and the like, suitable for sharing information and a variety of data. The collaboration layer 68 may also include cloud-based systems 70 or communicate with the cloud-based systems 70 that may provide for decentralized computing services and file storage. For example, portions (or all) of the systems 30, 32, 34, 36, 38 may be stored in the cloud 70 and/or accessible via the cloud 70.

The extensibility and customization systems 42, 44, 46, 48, 50, and 52 may provide for functionality not found natively in the CAR system 30, the CAD system 32, the CAE system 34, the CAM/CIM system 36, the CMM system 38 and/or the PDM system 40. For example, computer code or instructions may be added to the systems 30, 32, 34, 36, 38, and/or 40 via shared libraries, modules, software subsystems and the like, included in the extensibility and customization systems 42, 44, 46, 48, 50, and/or 52. The extensibility and customization systems 42, 44, 46, 48, 50, and 52 may also use application programming interfaces (APIs) included in their respective systems 30, 32, 34, 36, 38, and 40 to execute certain functions, objects, shared data, software systems, and so on, useful in extending the capabilities of the CAR system 30, the CAD system 32, the CAM/CIM system 36, the CMM system 38 and/or the PDM system 40. By enabling the processes 12, 14, 16, 18, 20, and 22, for example, via the systems 30, 32, 34, 36, and 38 and their respective extensibility and customization systems 42, 44, 46, 48, 50, and 52, the techniques described herein may provide for a more efficient “cradle-to-grave” product lifecycle management.

For example, the extensibility and customization system 44 of the CAD system 32 may be used to determine whether PMI objects (e.g., annotations) presented with a model are readable. For instance, the extensibility and customization system 44 may determine a readability (e.g., a readability metric) of PMI annotations that are presented with a model 80, determine whether the readability is equal to or greater than a threshold readability level, and generate another view of the model 80 when the first view in which the model 80 is presented has a readability that is below the threshold.

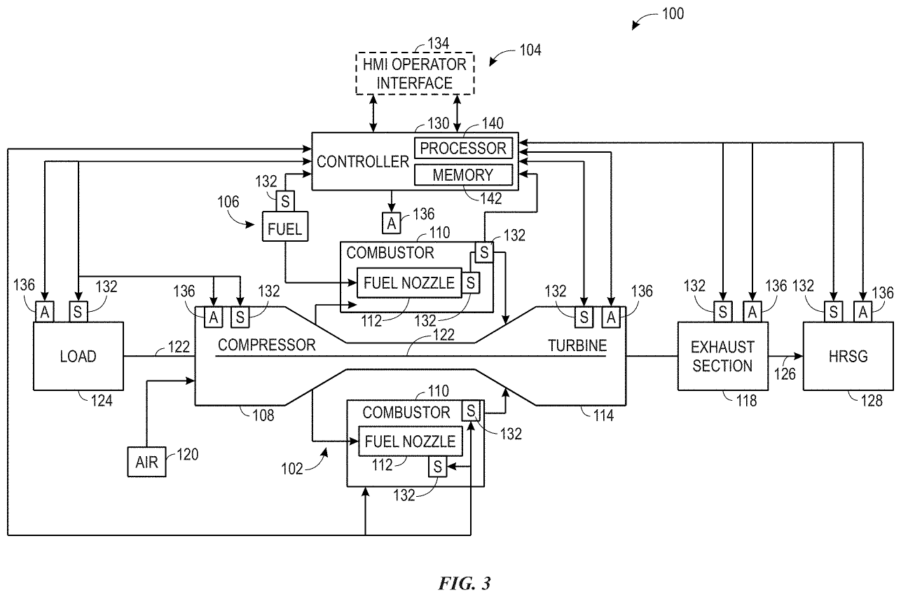

It may be beneficial to describe a machine that may incorporate one or more parts manufactured and tracked by the processes 12, 14, 16, 18, 20, and 22, for example, via the CAx system 10. Accordingly, FIG. 3 illustrates an example of a power production system 100 that may be entirely (or partially) conceived, developed, engineered, manufactured, serviced, and tracked by the CAx system 10. As illustrated in FIG. 1, the power production system 100 includes a gas turbine system 102, a monitoring and control system 104, and a fuel supply system 106. The gas turbine system 102 may include a compressor 108, combustion systems 110, fuel nozzles 112, a gas turbine 114, and an exhaust section 118. During operation, the gas turbine system 102 may pull air 120 into the compressor 108, which may then compress the air 120 and move the air 120 to the combustion system 110 (e.g., which may include a number of combustors). In the combustion system 110, the fuel nozzle 112 (or a number of fuel nozzles 112) may inject fuel that mixes with the compressed air 120 to create, for example, an air-fuel mixture.

The air-fuel mixture may combust in the combustion system 110 to generate hot combustion gases, which flow downstream into the turbine 114 to drive one or more turbine stages. For example, the combustion gases may move through the turbine 114 to drive one or more stages of turbine blades, which may in turn drive rotation of a shaft 122. The shaft 122 may connect to a load 124, such as a generator that uses the torque of the shaft 122 to produce electricity. After passing through the turbine 114, the hot combustion gases may vent as exhaust gases 126 into the environment by way of the exhaust section 118. The exhaust gas 126 may include gases such as carbon dioxide (CO2), carbon monoxide (CO), nitrogen oxides (NOₓ), and so forth.

The exhaust gas 126 may include thermal energy, and the thermal energy may be recovered by a heat recovery steam generation (HRSG) system 128. In combined cycle systems, such as the power production system 100, hot exhaust 126 may flow from the gas turbine 114 and pass to the HRSG 128, where it may be used to generate high-pressure, high-temperature steam. The steam produced by the HRSG 128 may then be passed through a steam turbine engine for further power generation. In addition, the produced steam may also be supplied to any other processes where steam may be used, such as to a gasifier used to combust the fuel to produce the untreated syngas. The gas turbine engine generation cycle is often referred to as the “topping cycle,” whereas the steam turbine engine generation cycle is often referred to as the “bottoming cycle.” Combining these two cycles may lead to greater efficiencies in both cycles. In particular, exhaust heat from the topping cycle may be captured and used to generate steam for use in the bottoming cycle.

In certain embodiments, the system 100 may also include a controller 130. The controller 130 may be communicatively coupled to a number of sensors 132, a human machine interface (HMI) operator interface 134, and one or more actuators 136 suitable for controlling components of the system 100. The actuators 136 may include valves, switches, positioners, pumps, and the like, suitable for controlling the various components of the system 100. The controller 130 may receive data from the sensors 132, and may be used to control the compressor 108, the combustors of the combustion system 110, the turbine 114, the exhaust section 118, the load 124, the HRSG 128, and so forth.

In certain embodiments, the HMI operator interface 134 may be executable by one or more computer systems of the system 100. A plant operator may interface with the industrial system 10 via the HMI operator interface 134. Accordingly, the HMI operator interface 134 may include various input and output devices (e.g., mouse, keyboard, monitor, touch screen, or other suitable input and/or output device) such that the plant operator may provide commands (e.g., control and/or operational commands) to the controller 130.

The controller 130 may include a processor(s) 140 (e.g., a microprocessor(s)) that may execute software programs to control the industrial system 10 and components thereof. Moreover, the processor 140 may include multiple microprocessors, one or more “general-purpose” microprocessors, one or more special-purpose microprocessors, and/or one or more application specific integrated circuits (ASICS), or some combination thereof. For example, the processor 140 may include one or more reduced instruction set (RISC) processors. The controller 130 may include a memory device 142 that may store information such as control software, look up tables, configuration data, etc. The memory device 142 may include a tangible, non-transitory, machine-readable medium, such as a volatile memory (e.g., a random access memory (RAM)) and/or a nonvolatile memory (e.g., a read-only memory (ROM), flash memory, a hard drive, or any other suitable optical, magnetic, or solid-state storage medium, or a combination thereof).

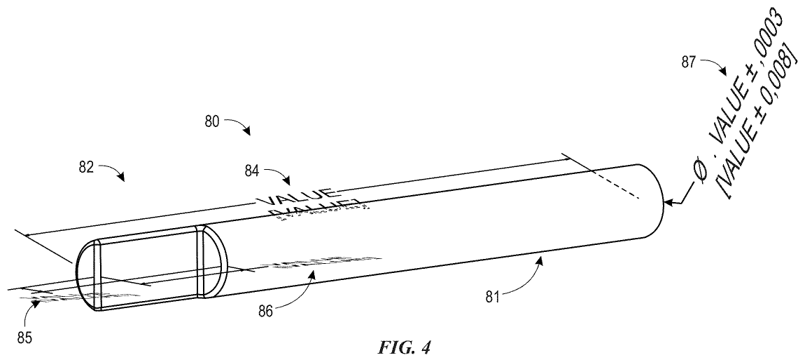

Drawings and/or models for the aforementioned parts of the industrial machinery may be generated to aid in the processes 12, 14, 16, 18, 20, and 22, for example, via the CAx system 10. More specifically, the models may include PMI information 84-87 displayed as objects (e.g., GUI objects such as annotations, callouts, notes, and/or text indicative of PMI) that are found in a model 80 of a part 81, as shown in FIG. 4. More specifically, FIG. 4 illustrates an embodiment of a view 82 of the model 80 with PMI information 84-87 that may be presented by a GUI of the CAD system 32.

In more detail, the model 80 generated by the CAD system 32 may be a model-based definition of a part or an assembly of, for example, industrial machinery. That is, a model 80 may be a 3D representation of the part, such that the 3D representation of the part may be manipulated and/or oriented to any given view on the CAD system 32 via inputs to a graphical user interface on the CAD system 32. For example, the graphical user interface may contain an arrow that may be used (e.g., via a user input like a computer mouse) to manipulate and/or orient the model 80 of a part to a specified view. As such, some views of the model 80 may contain more details or different details than that of other views. For example, a front view of a model 80 may show features (e.g., edges, faces, curves, holes) only on the front face of the part displayed by model 80, that may not be show in other views.

Furthermore, PMI information 84-87 may be associated with the model 80 or portions of the model 80. The PMI information 84-87 may be stored in the memory or the data-sharing layer mentioned above. As mentioned above, PMI information 84-87 may be any description of the feature that may be used and aid in the manufacturing of the feature into a part containing said feature. For example, the model 80 may be a part of industrial machinery, such that the part certain curves, edges, finishes, tolerances, and so on. In certain embodiments, the generated PMI information 84-87 may be compiled and stored in the memory and/or data repositories mentioned above. That is, the PMI associations 74, their respective features, association type, and criteria may be stored as part of the PMI data 76. PMI object displayed on the model may be generated from the PMI data 76. The PMI object may include a text description of the feature that is displayed on the model of the part. For example, a PMI object for a given through-hole (e.g., or any other feature) may include, as an annotation displayed on the model, text indicating the dimensions (e.g., radius, thread sizes, and/or any other PMI) of the hole. The PMI data 76 may be retrieved by the processor of the CAD system 32 to generate drawings with PMI objects (e.g., text indicative of PMI associated with a part and/or feature).

In some cases, the PMI information 84-87 associated with a model, such as the model 80, may be difficult to read. For instance, the orientation of the model 80 and/or some of the PMI information 84-87 may be such that PMI information, such as PMI information 84-86 is difficult to view. The CAD system 32, or in more particular, the extensibility and customization system 44 of the CAD system 32 may determine the readability of each piece of PMI information 84-87 based on the orientation of the model 80, the orientation of the PMI information 84-87, the size of the PMI information 84-87, and the font of the PMI information. For instance, the CAD system 32 may determine that the view 82 illustrated in FIG. 4 results in a low readability because the PMI information 84-86 appears perpendicular to the plane as the view 82 or nearly perpendicular to the plane of the view 82. For example, the CAD system 32 may determine a readability metric, such as a rating on a scale from zero to one-hundred, for the view 82 of the model 80. In other words, for a given view (e.g., how the model 80 and PMI information 84-87 are displayed to a user), the CAD system 32 may determine a readability metric associated the view to determine whether the PMI information 84-87 is readable.

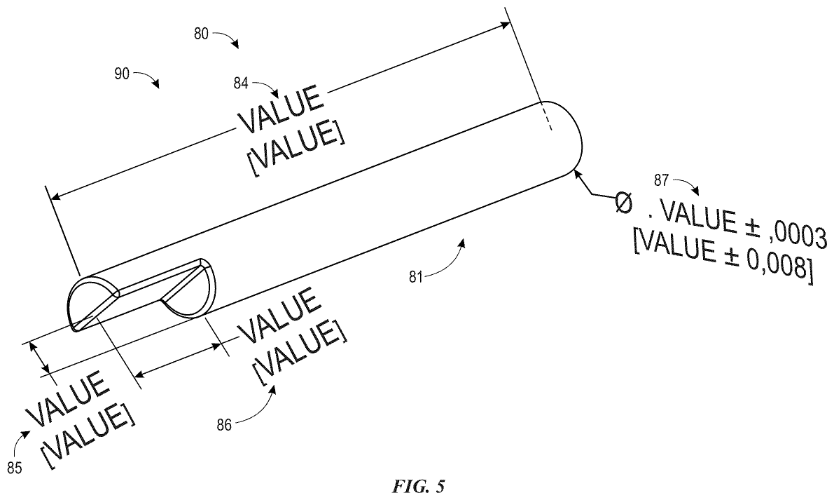

The CAD system 32 may present a view of the model 80 with PMI information that is determined to be readable. For instance, upon determining a readability of the model 80 and the PMI information 84-87, the CAD system 32 may compare the readability (e.g., readability metric) to a threshold readability, which may be a predetermined value. For views that are determined to be unreadable (e.g., below the threshold), the CAD system 32 may determine a different view and present the model 80 and PMI information 84-87 in the different view. For instance, FIG. 5 illustrates a second view 90 of the model 80 of part 81 that may be generated by the CAD system 32. Compared to the view presented in FIG. 4, the model 80 of FIG. 5 and/or the PMI information 84-87 have been rotated to increase the readability of the PMI information 84-87. Additionally, it should be noted that while the discussion above determining a different view for a model when the readability metric below a threshold, in other embodiments, the readability metric may be defined such that the determination as to whether a view is readable may be based on determining whether the readability metric is greater than the threshold.

The CAD system 32 may assign a sub-readability score that is specific to each PMI information 84-87. When determining a new view (e.g., the second view 90) for the model 80 and the PMI information 84-87, the CAD system 32 may present a new view in which each piece of PMI information 84-87 exceeds a threshold readability, a new view in which the highest average or median readability is achieved for the PMI information, or a combination of both. For instance, the CAD system 32 may generate a new view in which the sub-readability of each piece of PMI information 84-87 exceeds a threshold and the average sub-readability for each piece of PMI information 84-87 is maximized and/or exceeds the same threshold or another threshold. In some embodiments, the average sub-readability may be an arithmetic mean, while in other embodiments, the average sub-readability may be a weighted average (e.g., weighted based on a characteristic of a piece of PMI, such as a location within a view or relative to a part in a model.”

Furthermore, the CAD system 32 may employ machine learning systems (e.g., neural networks, support vector machines, data mining clustering systems, and so on), that are trained to determine whether PMI is readable. For example, the machine learning systems may be trained to determine how to determine whether PMI is readable (e.g., based on a comparison of the PMI readability metric to a threshold, a comparison of each sub-readability to the same threshold or a different threshold, an average of the sub-readabilities to the same threshold or a different threshold, or a combination thereof). Moreover, the machine learning systems may adjust predetermined values for thresholds utilized by the CAD system 32 as well as adjust how the readability metric and sub-readabilities are determined.

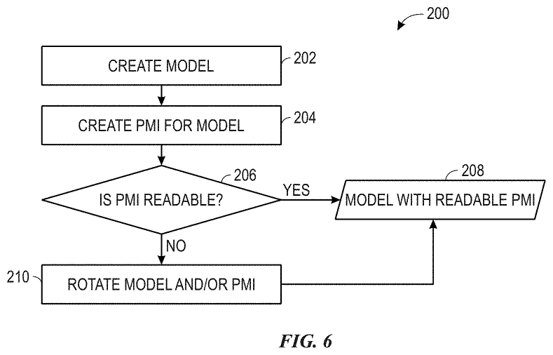

Keeping the discussion of FIG. 4 and FIG. 5 in mind, FIG. 6 is a flowchart of a process 200 for increasing the readability of PMI information associated with a model, such as the PMI information 84-87 associated with the model 80. The process 200 may be performed by a processor (e.g., processor 24) executing the CAD system 32. At process block 202, the CAD system 32 may generate a model, such as the model 80. Indeed, as discussed above, the model 80 may be a drawing of a part or an assembly of, for example, industrial machinery. That is, a model 80 may be a 3D representation of the part, such that the 3D representation of the part may be manipulated and/or oriented to any given view on the CAD system 32 via inputs to a user interface on the CAD system 32.

At process block 204, the CAD system 32 may generate PMI, such as PMI information 84-87, for the model 80. The PMI information 84-87 may provide information regarding the model 80, such as lengths, tolerances, or other information associated with the model 80 or portions thereof.

At decision block 206, the CAD system 32 may determine whether the PMI information 84-87 is readable. For example, as discussed above, the CAD system 32 may determine a readability metric associated with a view of the model 80 and the PMI information 84-87. The CAD system 32 may compare the readability metric to a threshold. When the determined readability metric is equal to or greater than the threshold, the CAD system 32 may determine that PMI information 84-87 of the presented view is readable. Additionally, as discussed above, the CAD system 32 may determine a sub-readability metric for each piece of PMI information 84-87. When the sub-readabilities for each piece of PMI information 84-87 are determined, the CAD system 32 may determine that a view has readable PMI information 84-87 when each piece of PMI information 84-87 is associated with a sub-readability that exceeds the threshold. In any case, when the CAD system 32 determined the PMI information 84-87 is readable, the CAD system 32 may generate and output a model with readable PMI 208.

However, if the CAD system 32 determines that the PMI information 84-87 is not readable, at process block 210, the CAD system 32 may rotate the model 80, the PMI information 84-87, or both, resulting in the model with readable PMI 208. In addition to, or as an alternative to, rotating the model 80 or the PMI information 84-87, the CAD system 32 may also increase a size of the PMI information 84-87 and/or change a font of the PMI information 84-87. In other words, when the CAD system 32 determines that the PMI information 84-87 associated with a model (e.g., model 80) is not readable, the CAD system 32 may determine another view that is readable and present that view (e.g., via a graphical user interface associated with the CAD system 32).

Technical effects of the presently disclosed techniques include enhanced readability of PMI information associated with CAD models. In particular, the techniques discussed above improve the ability of processors and CAD systems to determine whether PMI associated with a model is readable. Furthermore, the presently disclosed techniques enable processors and CAD systems to generate new views of models and PMI information when a view is determined to be unreadable.

This written description uses examples to disclose the claimed subject matter, including the best mode, and also to enable any person skilled in the art to practice the claimed disclosure, including making and using any devices or systems and performing any incorporated methods. The patentable scope of the claimed disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

1. A system comprising:
a processor for implementing a computer-aided technology (CAx) system, the CAx system comprising a graphical-user-interface (GUI) configured to present a first view of a computer-aided design (CAD) model, the CAD model comprising at least one part; and
memory storing instructions configured to cause the processor to:
generate a product and manufacturing information (PMI) associated with the CAD model;
present the CAD model with the PMI via the GUI; and
determine a PMI readability metric.

2. The system of claim 1, wherein the instructions are configured to cause the processor to reposition the PMI via the GUI when the PMI readability metric is less than a threshold.

3. The system of claim 2, wherein the instructions are configured to cause the processor to determine the PMI readability metric based on an orientation of the CAD model within the first view.

4. The system of claim 2, wherein the instructions are configured to cause the processor to determine the PMI readability metric based on an orientation of the PMI relative to the at least one part of the CAD model.

5. The system of claim 2, wherein the instructions are configured to cause the processor to determine the PMI readability metric based on a size of the PMI, a font of the PMI, or both.

6. The system of claim 1, wherein the PMI comprises a plurality of pieces of PMI, wherein the memory comprises instructions configured to cause the processor to determine the PMI readability metric by determining a PMI sub-readability metric associated with each of the plurality of pieces of PMI.

7. The system of claim 6, wherein the instructions are configured to cause the processor to determine whether the PMI readability metric is less than a threshold by determining whether each PMI sub-readability metrics is less than the threshold.

8. The system of claim 6, wherein the instructions are configured to cause the processor to determine whether the PMI readability metric is less than a threshold by determining whether an average of the sub-readabilities is less than the threshold.

9. The system of claim 1, wherein the instructions are configured to cause the processor to generate a second view of the model and PMI when the PMI readability metric exceeds a threshold.

10. The system of claim 9, wherein the instructions are configured to cause the processor to generate the second view by rotating the at least one part, the PMI, or both.

11. A computer-implemented method, comprising:
presenting a first computer-aided design (CAD) model in a graphical-user-interface (GUI), the first CAD model comprising at least one part;
generating a product and manufacturing information (PMI) associated with the CAD model;
presenting, via the GUI, the CAD model with the PMI;
determining a PMI readability metric;
comparing the PMI readability metric to a threshold; and
altering the presentation of the model and the PMI when the PMI readability is less than the threshold.

12. The computer-implemented method of claim 11, wherein the model comprises a plurality of PMI, wherein the computer-implemented method further comprises:
determining a sub-readability for each piece of the plurality of PMI;
determining whether each sub-readability exceeds the threshold;
determining whether an average of the sub-readabilities is greater than a second threshold; and
altering the presentation of the model and the PMI when at least one sub-readability is below the threshold or the average of the sub-readabilities is less than the second threshold.

13. The computer-implemented method of claim 12, comprising determining, via a machine learning system, whether to alter the presentation of the model and PMI based on when the at least one sub-readability is below the threshold, when the average of the sub-readabilities is less than the second threshold, or both.

14. The computer-implemented method of claim 11, comprising manufacturing the at least one part based on the altered presentation of the model and the PMI.

15. A tangible, non-transitory, computer-readable medium, comprising computer-readable instructions that, when executed by one or more processors of a computer, cause the one or more processors to:
present a first view of a computer-aided design (CAD) model, the CAD model comprising at least one part;
generate a product and manufacturing information (PMI) associated with the CAD model;
display a first view of the CAD model with the PMI;
determine a PMI readability metric of the first view;
compare the PMI readability metric to a threshold; and
present a second view of CAD model and the PMI when the PMI readability metric is less than the threshold.

16. The tangible, non-transitory, computer-readable medium of claim 15, wherein the instructions are configured to cause the one or more processors to determine the PMI readability metric based on an orientation of the PMI.

17. The tangible, non-transitory, computer-readable medium of claim 16, wherein the instructions are configured to cause the one or more processors to determine the PMI readability metric based on a size of the PMI.

18. The tangible, non-transitory, computer-readable medium of claim 15, wherein the model is associated with a plurality of piece of PMI, wherein the instructions are configured to cause the one or more processors to determine a sub-readability associated with each piece of PMI.

19. The tangible, non-transitory, computer-readable medium of claim 18, wherein the instructions are configured to cause the one or more processors to:
compare each sub-readability to a second threshold; and
present the second view when at least one sub-readability is less than the second threshold.

20. The tangible, non-transitory, computer-readable medium of claim 15, wherein the instructions are configured to cause the one or more processors to execute a machine learning system to be trained to determine a value of the threshold.
